(19) United States
(12) Patent Application Publication
(10) Pub. No.: US 2026/0119748 A1
(43) Pub. Date: Apr. 30, 2026

(54) SYSTEMS, APPARATUSES, METHODS, AND COMPUTER PROGRAM PRODUCTS FOR INITIATING PERFORMANCE OF ONE OR MORE OPTIMIZED DESIGN IMPLEMENTATION ACTIONS

(71) Applicant: Honeywell International Inc., Charlotte, NC (US)

(72) Inventors: Sunil Anthon Bardeskar, Bangalore (IN); Ananda Vel Murugan Chandra Mohan, Madurai (IN); Ivan Borastero Villan, St. Germaine-en-Laye (FR); Chandrashekar V Srinivas, Bangalore (IN)

(21) Appl. No.: 18/911,734

(22) Filed: Oct. 10, 2024

(30) Foreign Application Priority Data
Aug. 9, 2024 (IN) 202411060381

(51) Int. Cl. G06F 30/27

(52) U.S. Cl. CPC G06F 30/27

(57) ABSTRACT

Systems, apparatuses, methods, and computer program products are provided herein. For example, a method includes identifying one or more images associated with a first item. In some embodiments, the method includes generating first item reconfiguration data by applying the one or more images to a tear down machine learning component of a composite item design optimization machine learning model. In some embodiments, the method includes extracting external related item data from one or more external sources using a related item extraction machine learning component of the composite item design optimization machine learning model. In some embodiments, the method includes generating second item reconfiguration data by applying the one or more images and the external related item data to a related item benchmark machine learning component of the composite item design optimization machine learning model. In some embodiments, the method includes initiating performance of one or more optimized design implementation actions.

### CROSS REFERENCE TO RELATED APPLICATIONS

This application claims the benefit of India Provisional Application No. 202411060381 filed Aug. 8, 2024, and entitled “SYSTEMS, APPARATUSES, METHODS, AND COMPUTER PROGRAM PRODUCTS FOR ITEM DESIGN OPTIMIZATION,” which is hereby incorporated by reference in its entirety.

### TECHNOLOGICAL FIELD

Embodiments of the present disclosure relate generally to systems, apparatuses, methods, and computer program products for initiating performance of one or more optimized design implementation actions.

### BACKGROUND

Applicant has identified many technical challenges and difficulties associated with systems, apparatuses, methods, and computer program products for initiating performance of one or more optimized design implementation actions. Through applied effort, ingenuity, and innovation, Applicant has solved problems related to systems, apparatuses, methods, and computer program products for initiating performance of one or more optimized design implementation actions by developing solutions embodied in the present disclosure, which are described in detail below.

### BRIEF SUMMARY

Various embodiments described herein relate to systems, apparatuses, methods, and computer program products for initiating performance of one or more optimized design implementation actions.

In accordance with one aspect of the disclosure, a method is provided. In some embodiments, the method includes identifying one or more images associated with a first item. In some embodiments, the method includes generating first item reconfiguration data by applying the one or more images to a tear down machine learning component of a composite item design optimization machine learning model. In some embodiments, the method includes extracting external related item data from one or more external sources using a related item extraction machine learning component of the composite item design optimization machine learning model. In some embodiments, the external related item data is associated with a related item. In some embodiments, the method includes generating second item reconfiguration data by applying the one or more images and the external related item data to a related item benchmark machine learning component of the composite item design optimization machine learning model. In some embodiments, the method includes initiating performance of one or more optimized design implementation actions in response to generation of the first item reconfiguration data or the second item reconfiguration data.

In some embodiments, the external related item data comprises one or more related images associated with the related item.

In some embodiments, the one or more external sources comprise an internet-based source.

In some embodiments, the method includes receiving impact value base data from an impact value database.

In some embodiments, the method includes generating third item reconfiguration data by applying the impact value base data to an impact value determination machine learning component of the composite item design optimization machine learning model.

In some embodiments, the method includes causing a first image of the one or more images to be rendered to an item design visualization interface component.

In some embodiments, the method includes generating one or more augmented reality elements by applying the first item reconfiguration data or the second item reconfiguration data to an augmented reality machine learning component of the composite item design optimization machine learning model.

In some embodiments, the method includes causing at least one of the one or more augmented reality elements to be overlaid the first image on the item design visualization interface component.

In some embodiments, the method includes causing the item design visualization interface component to be rendered to an item design visualization interface.

In some embodiments, the item design visualization interface is provided on an augmented reality device.

In some embodiments, the tear down machine learning component is configured to perform one or more computer vision techniques.

In some embodiments, initiating performance of the one or more optimized design implementation actions comprises causing an item manufacturing procedure associated with the first item to be modified.

In some embodiments, initiating performance of the one or more optimized design implementation actions comprises generating an item reconfiguration interface component.

In some embodiments, the item reconfiguration interface component comprises one or more of the first item reconfiguration data, the second item reconfiguration data, or third item reconfiguration data.

In some embodiments, initiating performance of the one or more optimized design implementation actions comprises causing the item reconfiguration interface component to be rendered to an item reconfiguration interface.

In some embodiments, initiating performance of the one or more optimized design implementation actions comprises causing an item component inventory record to be modified.

In accordance with another aspect of the disclosure, an apparatus is provided. In some embodiments, the apparatus comprises memory and one or more processors communicatively coupled to the memory. In some embodiments, the one or more processors are configured to identify one or more images associated with a first item. In some embodiments, the one or more processors are configured to generate first item reconfiguration data by applying the one or more images to a tear down machine learning component of a composite item design optimization machine learning model. In some embodiments, the one or more processors are configured to extract external related item data from one or more external sources using a related item extraction machine learning component of the composite item design optimization machine learning model. In some embodiments, the external related item data is associated with a related item. In some embodiments, the one or more processors are configured to generate second item reconfiguration data by applying the one or more images and the external related item data to a related item benchmark machine learning component of the composite item design optimization machine learning model. In some embodiments, the one or more processors are configured to initiate performance of one or more optimized design implementation actions in response to generation of the first item reconfiguration data or the second item reconfiguration data.

In some embodiments, the external related item data comprises one or more related images associated with the related item.

In some embodiments, the one or more processors are further configured to receive impact value base data from an impact value database.

In some embodiments, the one or more processors are further configured to generate third item reconfiguration data by applying the impact value base data to an impact value determination machine learning component of the composite item design optimization machine learning model.

In some embodiments, the one or more processors are further configured to cause a first image of the one or more images to be rendered to an item design visualization interface component.

In some embodiments, the one or more processors are further configured to generate one or more augmented reality elements by applying the first item reconfiguration data or the second item reconfiguration data to an augmented reality machine learning component of the composite item design optimization machine learning model.

In some embodiments, the one or more processors are further configured to cause at least one of the one or more augmented reality elements to be overlaid the first image on the item design visualization interface component.

In some embodiments, the one or more processors are further configured to cause the item design visualization interface component to be rendered to an item design visualization interface.

In some embodiments, to initiate performance of the one or more optimized design implementation actions comprises the one or more processors being further configured to cause an item manufacturing procedure associated with the first item to be modified.

In some embodiments, to initiate performance of the one or more optimized design implementation actions comprises the one or more processors being further configured to generate an item reconfiguration interface component.

In some embodiments, the item reconfiguration interface component comprises one or more of the first item reconfiguration data, the second item reconfiguration data, or third item reconfiguration data.

In some embodiments, to initiate performance of the one or more optimized design implementation actions comprises the one or more processors being further configured to cause the item reconfiguration interface component to be rendered to an item reconfiguration interface.

In some embodiments, to initiate performance of the one or more optimized design implementation actions comprises the one or more processors being further configured to cause an item component inventory record to be modified.

In accordance with another aspect of the disclosure, a computer program product is provided. In some embodiments, the computer program product includes at least one non-transitory computer-readable storage medium having computer program code stored thereon. In some embodiments, the computer program code, in execution with at least one processor, configures the computer program product for identifying one or more images associated with a first item. In some embodiments, the computer program code, in execution with at least one processor, configures the computer program product for generating first item reconfiguration data by applying the one or more images to a tear down machine learning component of a composite item design optimization machine learning model. In some embodiments, the computer program code, in execution with at least one processor, configures the computer program product for extracting external related item data from one or more external sources using a related item extraction machine learning component of the composite item design optimization machine learning model. In some embodiments, the external related item data is associated with a related item. In some embodiments, the computer program code, in execution with at least one processor, configures the computer program product for generating second item reconfiguration data by applying the one or more images and the external related item data to a related item benchmark machine learning component of the composite item design optimization machine learning model. In some embodiments, the computer program code, in execution with at least one processor, configures the computer program product for initiating performance of one or more optimized design implementation actions in response to generation of the first item reconfiguration data or the second item reconfiguration data

### BRIEF DESCRIPTION OF THE DRAWINGS

Having thus described certain example embodiments of the present disclosure in general terms, reference will now be made to the accompanying drawings, which are not necessarily drawn to scale, and wherein:

FIG. 1 illustrates an exemplary block diagram of an environment in which embodiments of the present disclosure may operate;

FIG. 2 illustrates an exemplary block diagram of an example apparatus that may be specially configured in accordance with one or more embodiments of the present disclosure;

FIG. 3 illustrates an architecture of an example item design optimization device in accordance with one or more embodiments of the present disclosure;

FIG. 4 illustrates an example interface in accordance with one or more embodiments of the present disclosure;

FIG. 5 illustrates an example interface in accordance with one or more embodiments of the present disclosure;

FIG. 6 illustrates a flowchart of an example method in accordance with one or more embodiments of the present disclosure;

FIG. 7 illustrates a flowchart of an example method in accordance with one or more embodiments of the present disclosure; and

FIG. 8 illustrates a flowchart of an example method in accordance with one or more embodiments of the present disclosure.

### DETAILED DESCRIPTION

Some embodiments of the present disclosure will now be described more fully herein with reference to the accompanying drawings, in which some, but not all, embodiments of the disclosure are shown. Indeed, various embodiments of the disclosure may be embodied in many different forms and should not be construed as limited to the embodiments set forth herein; rather, these embodiments are provided so that this disclosure will satisfy applicable legal requirements. Like reference numerals refer to like elements throughout.

As used herein, the term “comprising” means including but not limited to and should be interpreted in the manner it is typically used in the patent context. Use of broader terms such as comprises, includes, and having should be understood to provide support for narrower terms such as consisting of, consisting essentially of, and comprised substantially of.

The phrases “in one embodiment,” “according to one embodiment,” “in some embodiments,” and the like generally mean that the particular feature, structure, or characteristic following the phrase may be included in at least one embodiment of the present disclosure and may be included in more than one embodiment of the present disclosure (importantly, such phrases do not necessarily refer to the same embodiment).

The word “example” or “exemplary” is used herein to mean “serving as an example, instance, or illustration. ” Any implementation described herein as “exemplary” is not necessarily to be construed as preferred or advantageous over other implementations.

If the specification states a component or feature “may,” “can,” “could,” “should,” “would,” “preferably,” “possibly,” “typically,” “optionally,” “for example,” “often,” or “might” (or other such language) be included or have a characteristic, that a specific component or feature is not required to be included or to have the characteristic. Such a component or feature may be optionally included in some embodiments or it may be excluded.

The use of the term “circuitry” as used herein with respect to components of a system or an apparatus should be understood to include particular hardware configured to perform the functions associated with the particular circuitry as described herein. The term “circuitry” should be understood broadly to include hardware and, in some embodiments, software for configuring the hardware. For example, in some embodiments, “circuitry” may include processing circuitry, communication circuitry, input/output circuitry, and the like. In some embodiments, other elements may provide or supplement the functionality of particular circuitry. Alternatively, or additionally, in some embodiments, other elements of a system and/or apparatus described herein may provide or supplement the functionality of another particular set of circuitry. For example, a processor may provide processing functionality to any of the sets of circuitry, a memory may provide storage functionality to any of the sets of circuitry, communications circuitry may provide network interface functionality to any of the sets of circuitry, and/or the like.

### Overview

Example embodiments disclosed herein address technical problems associated with systems, apparatuses, methods, and computer program products for item design optimization. As would be understood by one skilled in the field to which this disclosure pertains, there are numerous example scenarios in which systems, apparatuses, methods, and computer program products for item design optimization are desirable.

In many applications, it may be desirable to use systems, apparatuses, methods, and computer program products for item design optimization. For example, it may be desirable to use systems, apparatuses, methods, and computer program products for item design optimization to modify items such that items are more efficient, lighter, and have greater capabilities. In some implementations, it may be desirable to use systems, apparatuses, methods, and computer program products that are configured to perform item design optimization using tear down images of items and/or using augmented reality.

Example solutions for item design optimization include using a computing device to perform item design optimization. However, such example solutions are inefficient, reactive, and simplistic. For example, such example solutions are inefficient because such example solutions do not use a composite item design optimization machine learning that includes a plurality of specifically configured components for performing particular aspects of item design optimization. As a result, such example solutions cause computing devices to suffer from high latency, consume excessive processing power, and consume excessive memory. As another example, such example solutions are reactive because such example solutions are unable to automatically implement optimized design implementation actions. In this regard, such example solutions are unable to automatically implement optimized design implementation actions that automatically cause item manufacturing procedures to be modified and/or item component inventory records to be modified. As another example, such example solutions are simplistic because such example solutions are unable to implement optimized design implementation actions based on tear down images and using augmented reality. Accordingly, there is a need for systems, apparatuses, methods, and computer program products that are able to perform item design optimization in an efficient, a proactive, and a sophisticated manner.

Thus, to address these and/or other issues related to systems, apparatuses, methods, and computer program products for item design optimization, example systems, apparatuses, methods, and computer program products for item design optimization are disclosed herein. For example, an embodiment in this disclosure, described in greater detail below, includes a method that includes identifying one or more images associated with a first item. In some embodiments, the method includes generating first item reconfiguration data by applying the one or more images to a tear down machine learning component of a composite item design optimization machine learning model. In some embodiments, the method includes extracting external related item data from one or more external sources using a related item extraction machine learning component of the composite item design optimization machine learning model. In some embodiments, the external related item data is associated with a related item. In some embodiments, the method includes generating second item reconfiguration data by applying the one or more images and the external related item data to a related item benchmark machine learning component of the composite item design optimization machine learning model. In some embodiments, the method includes initiating performance of one or more optimized design implementation actions in response to generation of the first item reconfiguration data or the second item reconfiguration data. Accordingly, the systems, apparatuses, methods, and computer program products enable item design optimization in an efficient, proactive, and sophisticated manner.

### Example Systems and Apparatuses

Embodiments of the present disclosure herein include systems, apparatuses, methods, and computer program products configured for item design optimization. For example, embodiments of the present disclosure herein may include systems, apparatuses, methods, and computer program products configured for item design optimization using value engineering (VE) and/or component engineering (CE). In some embodiments, value engineering and/or component engineering includes facilitating the lifecycle management of an item. It should be readily appreciated that the embodiments of the apparatus, systems, methods, and computer program product described herein may be configured in various additional and alternative manners in addition to those expressly described herein.

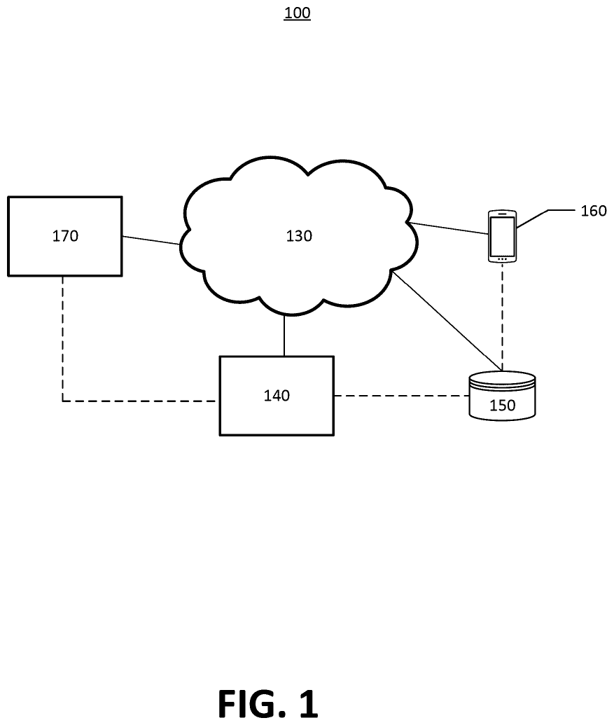

FIG. 1 illustrates an exemplary block diagram of an environment in which embodiments of the present disclosure may operate. In some embodiments, the environment 100 includes an item design optimization device 140. In some embodiments, the item design optimization device 140 is electronically and/or communicatively coupled to one or more databases 150, an augmented reality device 170, and/or user device 160. The item design optimization device 140 may be located remotely from the one or more databases 150, the augmented reality device 170, and/or the user device 160. In some embodiments, the item design optimization device 140 may be located in a remote cloud server and electronically and/or communicatively coupled to the one or more databases 150, the augmented reality device 170, and/or user device 160 via at least a network 130. In some embodiments, the item design optimization device 140 is configured via hardware, software, firmware, and/or a combination thereof, to perform data intake of one or more types of data, such as one or more images (e.g., individual images and/or videos), first item reconfiguration data, second item reconfiguration data, third item reconfiguration data, external related item data (e.g., including one or more related item images), impact value base data, and/or the like.

Additionally, or alternatively, in some embodiments, the item design optimization device 140 is configured via hardware, software, firmware, and/or a combination thereof, to generate and/or transmit command(s) that control, adjust, or otherwise impact operations of the one or more of the one or more databases 150, the augmented reality device 170, the item design optimization device 140, and/or the user device 160. For example, the item design optimization device 140 may be configured to perform item design optimization. In some embodiments, performing item design optimization includes initiating performance of one or more optimized design implementation actions. Additionally, or alternatively, in some embodiments, the item design optimization device 140 is configured via hardware, software, firmware, and/or a combination thereof, to perform data reporting, provide data, and/or other data output process(es) associated with monitoring or otherwise analyzing operations of one or more of the one or more of the one or more databases 150, the augmented reality device 170, the item design optimization device 140, and/or the user device 160. For example, in various embodiments, the item design optimization device 140 may be configured to execute and/or perform one or more operations and/or functions described herein.

In some embodiments, the environment 100 includes the augmented reality device 170. In some embodiments, the augmented reality device 170 is electronically and/or communicatively coupled to the one or more databases 150, the item design optimization device 140, and/or the user device 160. The augmented reality device 170 may be located remotely from the one or more databases 150, the item design optimization device 140, and/or the user device 160. In some embodiments, the augmented reality device 170 may be electronically and/or communicatively coupled to the one or more databases 150, the item design optimization device 140, and/or user device 160 via at least a network 130. In some embodiments, the augmented reality device 170 is configured via hardware, software, firmware, and/or a combination thereof, to perform data intake of one or more types of data, such as one or more images (e.g., individual images and/or videos), first item reconfiguration data, second item reconfiguration data, third item reconfiguration data, external related item data (e.g., including one or more related item images), impact value base data, and/or the like.

Additionally, or alternatively, in some embodiments, the augmented reality device 170 is configured via hardware, software, firmware, and/or a combination thereof, to generate and/or transmit command(s) that control, adjust, or otherwise impact operations of the one or more of the one or more databases 150, the item design optimization device 140, the augmented reality device 170, and/or the user device 160. For example, the augmented reality device 170 may be configured to facilitate augmented reality, mixed reality, extended reality, and/or the like. Additionally, or alternatively, in some embodiments, the augmented reality device 170 is configured via hardware, software, firmware, and/or a combination thereof, to perform data reporting, provide data, and/or other data output process(es) associated with monitoring or otherwise analyzing operations of one or more of the one or more of the one or more databases 150, the item design optimization device 140, the augmented reality device 170, and/or the user device 160. For example, in various embodiments, the augmented reality device 170 may be configured to execute and/or perform one or more operations and/or functions described herein. In some embodiments, the augmented reality device 170 is included in the item design optimization device 140. Said differently, in some embodiments, the item design optimization device 140 is configured to provide the functionality of the item design optimization device 140 and the augmented reality device 170.

The user device 160 may be associated with users of the item design optimization device 140. In various embodiments, the item design optimization device 140 may generate and/or transmit a message, alert, or indication to a user via the user device 160. Additionally, or alternatively, the user device 160 may be utilized by a user to remotely access the item design optimization device 140. This may be by, for example, an application operating on the user device 160.

The one or more databases 150 may be configured to receive, store, and/or transmit data. In various embodiments, the one or more databases may be associated with data associated with the item design optimization device 140, the augmented reality device 170, and/or the user device 160. Additionally, or alternatively, in some embodiments the one or more databases 150 store user inputted data. The one or more databases 150 may be located remotely from the user device 160, the augmented reality device 170, and/or the item design optimization device 140, in proximity of the user device 160 and/or the item design optimization device 140, the augmented reality device 170, and/or within the user device 160, the augmented reality device 170, and/or the item design optimization device 140. In some embodiments, the one or more databases 150 include one or more external sources (e.g., one or more external internet-based sources), an impact value database, and/or the like.

The network 130 may be embodied in any of a myriad of network configurations. In some embodiments, the network 130 may be a public network (e.g., the Internet). In some embodiments, the network 130 may be a private network (e.g., an internal localized, or closed-off network between particular devices). In some other embodiments, the network 130 may be a hybrid network (e.g., a network enabling internal communications between particular connected devices and external communications with other devices). In various embodiments, the network 130 may include one or more base station(s), relay(s), router(s), switch(es), cell tower(s), communications cable(s), routing station(s), and/or the like. In various embodiments, components of the environment 100 may be communicatively coupled to transmit data to and/or receive data from one another over the network 130. Such configuration(s) include, without limitation, a wired or wireless Personal Area Network (PAN), Local Area Network (LAN), Metropolitan Area Network (MAN), Wide Area Network (WAN), and/or the like.

Additionally, while FIG. 1 illustrates certain components as separate, standalone entities communicating over the network 130, various embodiments are not limited to this configuration. In other embodiments, one or more components may be directly connected and/or share hardware or the like. For example, in some embodiments, the item design optimization device 140 may include one or more databases 150.

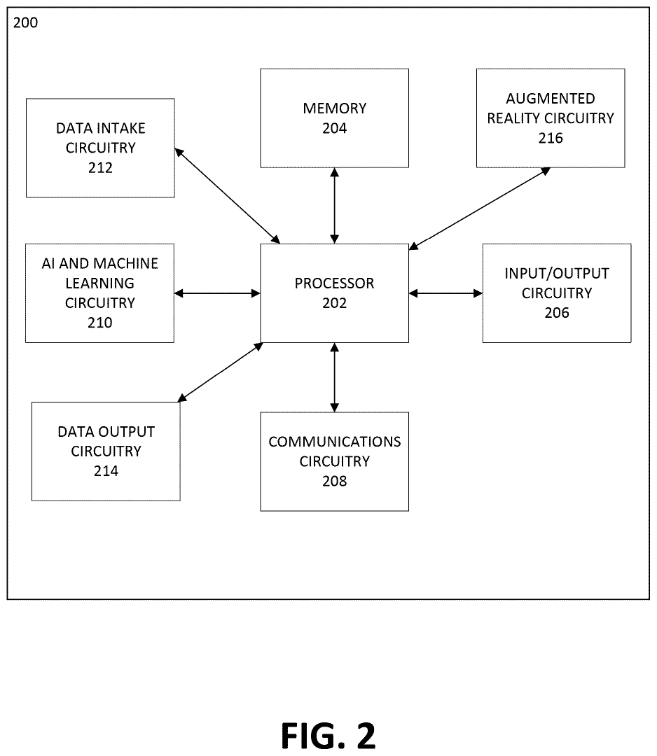

FIG. 2 illustrates an exemplary block diagram of an example apparatus that may be specially configured in accordance with an example embodiment of the present disclosure. Specifically, FIG. 2 depicts an example computing apparatus 200 (“apparatus 200”) specially configured in accordance with at least some example embodiments of the present disclosure. Examples of an apparatus 200 may include, but is not limited to, the one or more databases 150, the item design optimization device 140, and/or the user device 160. The apparatus 200 includes processor 202, memory 204, input/output circuitry 206, communications circuitry 208, artificial intelligence (“AI”) and machine learning circuitry 210, data intake circuitry 212, data output circuitry 214, and/or augmented reality circuitry. In some embodiments, the apparatus 200 is configured to execute and perform the operations described herein.

Although components are described with respect to functional limitations, it should be understood that the particular implementations necessarily include the use of particular computing hardware. It should also be understood that in some embodiments certain of the components described herein include similar or common hardware. For example, in some embodiments two sets of circuitry both leverage use of the same processor(s), memory(ies), circuitry(ies), and/or the like to perform their associated functions such that duplicate hardware is not required for each set of circuitry.

In various embodiments, such as an computing apparatus 200 of the one or more databases 150, the augmented reality device 170, the item design optimization device 140, and/or the user device 160 may refer to, for example, one or more computers, computing entities, desktop computers, mobile phones, tablets, phablets, notebooks, laptops, distributed systems, servers, or the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein. In one embodiment, these functions, operations, and/or processes can be performed on data, content, information, and/or similar terms used herein. In this regard, the apparatus 200 embodies a particular, specially configured computing entity transformed to enable the specific operations described herein and provide the specific advantages associated therewith, as described herein.

Processor 202 or processor circuity 202 may be embodied in a number of different ways. In various embodiments, the use of the terms “processor” should be understood to include a single core processor, a multi-core processor, multiple processors internal to the apparatus 200, and/or one or more remote or “cloud” processor(s) external to the apparatus 200. In some example embodiments, processor 202 may include one or more processing devices configured to perform independently. Alternatively, or additionally, processor 202 may include one or more processor(s) configured in tandem via a bus to enable independent execution of operations, instructions, pipelining, and/or multithreading.

In an example embodiment, the processor 202 may be configured to execute instructions stored in the memory 204 or otherwise accessible to the processor. Alternatively, or additionally, the processor 202 may be configured to execute hard-coded functionality. As such, whether configured by hardware or software methods, or by a combination thereof, processor 202 may represent an entity (e.g., physically embodied in circuitry) capable of performing operations according to embodiments of the present disclosure while configured accordingly. Alternatively, or additionally, processor 202 may be embodied as an executor of software instructions, and the instructions may specifically configure the processor 202 to perform the various algorithms embodied in one or more operations described herein when such instructions are executed. In some embodiments, the processor 202 includes hardware, software, firmware, and/or a combination thereof that performs one or more operations described herein.

In some embodiments, the processor 202 (and/or co-processor or any other processing circuitry assisting or otherwise associated with the processor) is/are in communication with the memory 204 via a bus for passing information among components of the apparatus 200.

Memory 204 or memory circuitry 204 may be non-transitory and may include, for example, one or more volatile and/or non-volatile memories. In some embodiments, the memory 204 includes or embodies an electronic storage device (e.g., a computer readable storage medium). In some embodiments, the memory 204 is configured to store information, data, content, applications, instructions, or the like, for enabling an apparatus 200 to carry out various operations and/or functions in accordance with example embodiments of the present disclosure.

Input/output circuitry 206 may be included in the apparatus 200. In some embodiments, input/output circuitry 206 may provide output to the user and/or receive input from a user. The input/output circuitry 206 may be in communication with the processor 202 to provide such functionality. The input/output circuitry 206 may comprise one or more user interface(s). In some embodiments, a user interface may include a display that comprises the interface(s) rendered as a web user interface, an application user interface, a user device, a backend system, or the like. In some embodiments, the input/output circuitry 206 also includes a keyboard, a mouse, a joystick, a touch screen, touch areas, soft keys a microphone, a speaker, or other input/output mechanisms. The processor 202 and/or input/output circuitry 206 comprising the processor may be configured to control one or more operations and/or functions of one or more user interface elements through computer program instructions (e.g., software and/or firmware) stored on a memory accessible to the processor (e.g., memory 204, and/or the like). In some embodiments, the input/output circuitry 206 includes or utilizes a user-facing application to provide input/output functionality to a computing device and/or other display associated with a user.

Communications circuitry 208 may be included in the apparatus 200. The communications circuitry 208 may include any means such as a device or circuitry embodied in either hardware or a combination of hardware and software that is configured to receive and/or transmit data from/to a network and/or any other device, circuitry, or module in communication with the apparatus 200. In some embodiments the communications circuitry 208 includes, for example, a network interface for enabling communications with a wired or wireless communications network. Additionally, or alternatively, the communications circuitry 208 may include one or more network interface card(s), antenna(s), bus(es), switch(es), router(s), modem(s), and supporting hardware, firmware, and/or software, or any other device suitable for enabling communications via one or more communications network(s). In some embodiments, the communications circuitry 208 may include circuitry for interacting with an antenna(s) and/or other hardware or software to cause transmission of signals via the antenna(s) and/or to handle receipt of signals received via the antenna(s). In some embodiments, the communications circuitry 208 enables transmission to and/or receipt of data from a user device and/or other external computing device(s) in communication with the apparatus 200.

Data intake circuitry 212 may be included in the apparatus 200. The data intake circuitry 212 may include hardware, software, firmware, and/or a combination thereof, designed and/or configured to capture, receive, request, and/or otherwise gather data associated with operations of the one or more databases 150, the item design optimization device 140, and/or the user device 160. In some embodiments, the data intake circuitry 212 includes hardware, software, firmware, and/or a combination thereof, that communicates with one or more components of the one or more databases 150, the augmented reality device 170, the item design optimization device 140, and/or the user device 160 to receive particular data associated with such operations of the one or more databases 150, the augmented reality device 170, the item design optimization device 140, and/or the user device 160. The data intake circuitry 212 may support such operations for the one or more databases 150, the item design optimization device 140, and/or the user device 160. Additionally, or alternatively, in some embodiments, the data intake circuitry 212 includes hardware, software, firmware, and/or a combination thereof, that retrieves particular data associated with the one or more databases 150, the item design optimization device 140, the augmented reality device 170, and/or the user device 160.

AI and machine learning circuitry 210 may be included in the apparatus 200. The AI and machine learning circuitry 210 may include hardware, software, firmware, and/or a combination thereof designed and/or configured to request, receive, process, generate, and transmit data, data structures, control signals, and electronic information for training and executing a trained AI and machine learning model configured to facilitating the operations and/or functionalities described herein. For example, in some embodiments the AI and machine learning circuitry 210 includes hardware, software, firmware, and/or a combination thereof, that identifies training data and/or utilizes such training data for training a particular machine learning model, AI, and/or other model to generate particular output data based at least in part on learnings from the training data. Additionally, or alternatively, in some embodiments, the AI and machine learning circuitry 210 includes hardware, software, firmware, and/or a combination thereof, that embodies or retrieves a trained machine learning model, AI and/or other specially configured model utilized to process inputted data. Additionally, or alternatively, in some embodiments, the AI and machine learning circuitry 210 includes hardware, software, firmware, and/or a combination thereof that processes received data utilizing one or more algorithm(s), function(s), subroutine(s), and/or the like, in one or more pre-processing and/or subsequent operations that need not utilize a machine learning or AI model.

Augmented reality circuitry 216 may be included in the apparatus 200. The augmented reality circuitry 216 may include hardware, software, firmware, and/or a combination thereof designed and/or configured to facilitate performance of augmented reality, extended reality, mixed reality, and/or the like. For example, the augmented reality circuitry 216 may include hardware, software, firmware, and/or a combination thereof designed and/or configured to generate one or more augmented reality elements. Additionally, or alternatively, the augmented reality circuitry 216 may include hardware, software, firmware, and/or a combination thereof designed and/or configured to control operations of the augmented reality device 170.

Data output circuitry 214 may be included in the apparatus 200. The data output circuitry 214 may include hardware, software, firmware, and/or a combination thereof, that configures and/or generates an output based at least in part on data processed by the apparatus 200. In some embodiments, the data output circuitry 214 includes hardware, software, firmware, and/or a combination thereof, that generates a particular report based at least in part on the processed data, for example where the report is generated based at least in part on a particular reporting protocol. Additionally, or alternatively, in some embodiments, the data output circuitry 214 includes hardware, software, firmware, and/or a combination thereof, that configures a particular output data object, output data file, and/or user interface for storing, transmitting, and/or displaying. For example, in some embodiments, the data output circuitry 214 generates and/or specially configures a particular data output for transmission to another system sub-system for further processing. Additionally, or alternatively, in some embodiments, the data output circuitry 214 includes hardware, software, firmware, and/or a combination thereof, that causes rendering of a specially configured user interface based at least in part on data received by and/or processing by the apparatus 200.

In some embodiments, two or more of the sets of circuitries 202-214 are combinable. Alternatively, or additionally, one or more of the sets of circuitry 202-214 perform some or all of the operations and/or functionality described herein as being associated with another circuitry. In some embodiments, two or more of the sets of circuitry 202-214 are combined into a single module embodied in hardware, software, firmware, and/or a combination thereof. For example, in some embodiments, one or more of the sets of circuitry, for example the AI and machine learning circuitry 210, may be combined with the processor 202, such that the processor 202 performs one or more of the operations described herein with respect the AI and machine learning circuitry 210.

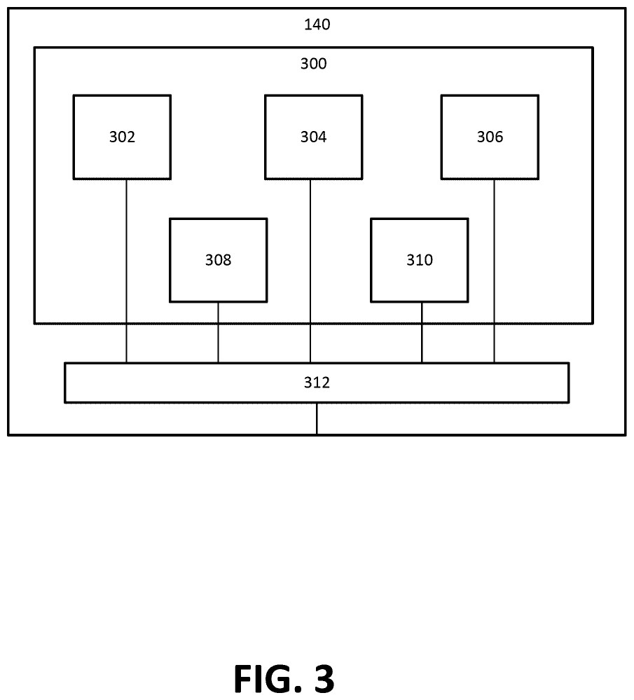

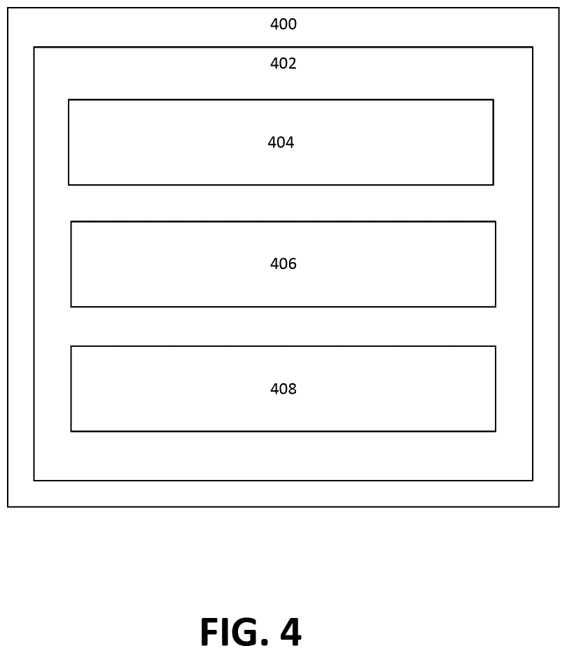

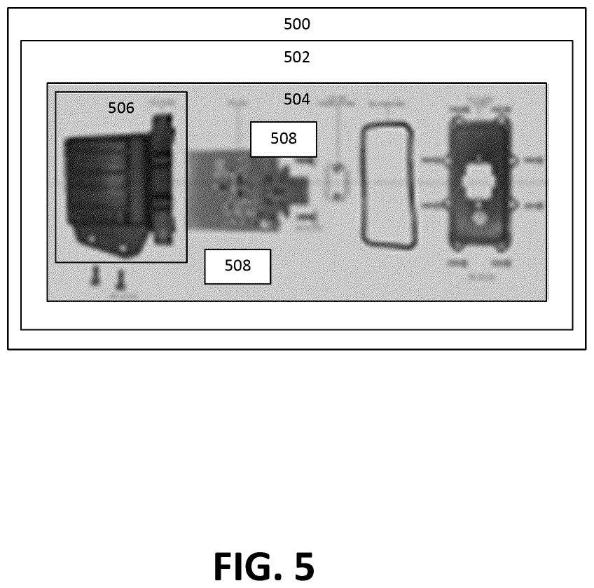

With reference to FIGS. 1-5, in some embodiments, an item, such as a first item and/or a related item, includes an electrical item, a mechanical item, an electromechanical item, a resin item, and/or the like. For example, an item may include a printed circuit board (PCB), a printed circuit board assembly (PCBA), a sensor, a bar code scanner, and/or the like. In some embodiments, an item includes one or more components that form a portion of the item. For example, a component of an item may include a portion of a printed circuit board (PCB) (e.g., an individual layer of a printed circuit board), a portion of a printed circuit board assembly (PCBA) (e.g., an individual electrical component of a printed circuit board assembly), a portion of a sensor (e.g., a controller of a sensor), a portion of a bar code scanner (e.g., a imagining component of a bar code scanner), and/or the like.

In some embodiments, the item design optimization device 140 is configured to identify one or more images associated with the first item. In some embodiments, the one or more images include images of a first item. For example, the one or more images may include images of a first item that includes a printed circuit board (PCB), a printed circuit board assembly (PCBA), a sensor, bar code scanner, and/or the like. In some embodiments, the one or more images include individual images of the first item, such as individual still images of the first item. For example, the one or more images may include one or more photos of the first item. In some embodiments, the one or more images include a series of images of the first item. For example, the one or more images may include a video of the first item. In some embodiments, the one or more images are captured using visible light, infrared, x-rays, and/or the like. In some embodiments, the one or more images include one or more tear down images of the first item. In this regard, for example, tear down images may include images of the first item after the first item has been taken apart and split into its components. As another example, tear down images may include images of the first item as the first item is being taken apart and split into the first item's components. Said differently, in some embodiments, the one or more images include tear down images that are configured to convey the first item's design, the first item's components, the first item's manufacturing process, and/or the like. In some embodiments, the one or more images are associated with item design configuration data. In this regard, for example, the item design optimization device 140 may be configured to identify item design configuration data that includes one or more images.

In some embodiments, identifying one or more images associated with the first item includes the item design optimization device 140 being configured to receive one or more images. For example, the item design optimization device 140 may be configured to receive one or more images from the one or more databases 150, the augmented reality device 170, the user device 160, and/or one or more other sources (e.g., remote sources). Additionally, or alternatively, identifying one or more images includes the item design optimization device 140 being configured to generate the one or more images associated with the first item. In this regard, for example, the item design optimization device 140 may include one or more image capture components (e.g., a camera) configured to capture one or more images.

In some embodiments, the item design optimization device 140 is configured to generate first item reconfiguration data. In some embodiments, first item reconfiguration data includes one or more items of data representative and/or indicative of one or more features of the first item that are determined by applying one or more images to a tear down machine learning component 302 of a composite item design optimization machine learning model 300. For example, first item reconfiguration data includes one or more items of data representative and/or indicative of one or more features of the first item that include a material from which the first item is constructed (e.g., the material of a layer of a PCB). As another example, first item reconfiguration data includes one or more items of data representative and/or indicative of one or more features of the first item that include a component of the first item (e.g., an electrical component, such as a capacitor, of a PCBA). As another example, first item reconfiguration data includes one or more items of data representative and/or indicative of one or more features of the first item that include a manufacturing process used to create and/or generate the first item (e.g., steps used to manufacture the first item). As another example, first item reconfiguration data includes one or more items of data representative and/or indicative of one or more features of the first item that include a machining process used to create and/or generate the first item (e.g., tools used to create a housing of a sensor).

Additionally, or alternatively, first item reconfiguration data includes one or more items of data representative and/or indicative of one or more actions that may be performed to improve the first item that are determined by applying one or more images to a tear down machine learning component 302 of a composite item design optimization machine learning model 300. In this regard, in some embodiments, first item reconfiguration data may be representative and/or indicative of actions that may be performed to optimize the design of the first item. For example, first item reconfiguration data may be representative and/or indicative of one or more actions that may be performed to improve the first item that include reducing the weight of a component of the first item (e.g., by replacing a component with a similar but lighter weight component). As another example, first item reconfiguration data may be representative and/or indicative of one or more actions that may be performed to improve the first item that include replacing a component of the first item having a high impact value (e.g., a high cost) with a similar component having a lower impact value (e.g., a lower cost). As another example, first item reconfiguration data may be representative and/or indicative of one or more actions that may be performed to improve the first item that include performing fewer manufacturing steps to manufacture the first item (e.g., a more streamlined manufacturing process that eliminates redundant or inefficient steps). As another example, first item reconfiguration data may be representative and/or indicative of one or more actions that may be performed to improve the first item that include altering a manufacturing processes to rely less on specialized tools to generate and/or create the first item. As another example, first item reconfiguration data may be representative and/or indicative of one or more actions that may be performed to improve the first item that include replacing a material of an item with another material (e.g., replacing steel with plastic). In some embodiments, first item reconfiguration data is associated with item design optimization implementation data. In this regard, in some embodiments, the item design optimization device 140 is configured to generate item design optimization implementation data that includes first item reconfiguration data.

In some embodiments, the tear down machine learning component 302 may be a data entity that describes parameters, hyper-parameters, and/or defined operations of a rules-based, machine learning model, and/or generative artificial intelligence model (e.g., model including at least one of one or more rule-based layers, one or more layers that depend on trained parameters, coefficients, and/or the like) configured to generate first item reconfiguration data. In this regard, in some embodiments, the tear down machine learning component 302 may be configured to utilize one or more of any type of machine learning, rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. For example, the tear down machine learning component 302 may be configured to employ computer vision techniques to analyze one or more images to identify one or more features of the first item and/or one or more actions that may be performed to improve the first item. In some embodiments, the tear down machine learning component 302 is one component of the composite item design optimization machine learning model 300. In this regard, in some embodiments, the tear down machine learning component 302 is configured to communicate with one or more other components of the composite item design optimization machine learning model 300 via a bus 312.

In some embodiments, the item design optimization device 140 is configured to extract external related item data from one or more external sources. In some embodiments, the one or more external sources comprise an internet-based source. In some embodiments, external related item data includes one or more items of data representative and/or indicative of the related item. In this regard, for example, the related item may be an item that is related to the first item. In some embodiments, the related item is related to the first item because the related item and the first item have one or more features that are similar and/or in common with each other. For example, the related item may have one or more features that are similar and/or in common with the one or more features of the first item that were identified by the tear down machine learning component 302 (e.g., when the tear down machine learning component 302 generated first item reconfiguration data). Additionally, or alternatively, the related item and the first item may be related because the related item and the first item may have a common or similar manufacturing bill of materials (MBOM), a common or similar component specification, a common or similar manufacturing process and specification, a common or similar provider detail specification, and/or the like.

In some embodiments, the external related item data includes one or more related images. In some embodiments, the one or more related images include images of the related item. For example, the one or more related images may include images of a related item that includes a printed circuit board (PCB), a printed circuit board assembly (PCBA), a sensor, bar code scanner, and/or the like. In some embodiments, the one or more related images include individual images of the related item, such as individual still images of the related item. For example, the one or more related images may include one or more photos of the related item. In some embodiments, the one or more related images include a series of images of the related item. For example, the one or more related images may include a video of the related item. In some embodiments, the one or more related images are captured using visible light, infrared, x-rays, and/or the like. In some embodiments, the one or more related images include one or more tear down images of the related item. In this regard, for example, tear down images may include images of the related item after the related item has been taken apart and split into its components. As another example, tear down images may include images of the related item as the related item is being taken apart and split into the related item's components. Said differently, in some embodiments, the one or more related images include tear down images that are configured to convey the related item's design, the related item's components, the related item's manufacturing process, and/or the like. In some embodiments, the one or more related images are associated with item design configuration data. In this regard, for example, the item design optimization device 140 may be configured to identify item design configuration data that includes one or more related images.

In some embodiments, the related item extraction machine learning component 304 may be a data entity that describes parameters, hyper-parameters, and/or defined operations of a rules-based, machine learning model, and/or generative artificial intelligence model (e.g., model including at least one of one or more rule-based layers, one or more layers that depend on trained parameters, coefficients, and/or the like) configured to extract external related item data from one or more external sources. In this regard, in some embodiments, the related item extraction machine learning component 304 may be configured to utilize one or more of any type of machine learning rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. For example, if the related item extraction machine learning component 304 may be configured to employ one or more fuzzy similarity techniques to identify and extract external related item data that is indicative of the related item based on the related item's commonality with the first item. In some embodiments, the related item extraction machine learning component 304 is one component of the composite item design optimization machine learning model 300. In this regard, in some embodiments, the related item extraction machine learning component 304 is configured to communicate with one or more other components of the composite item design optimization machine learning model 300 via a bus 312.

In some embodiments, the item design optimization device 140 is configured to generate second item reconfiguration data. In some embodiments, the item design optimization device 140 is configured to generate second item reconfiguration data using a related item benchmark machine learning component 306 of the composite item design optimization machine learning model 300. In some embodiments, the related item benchmark machine learning component 306 may be a data entity that describes parameters, hyper-parameters, and/or defined operations of a rules-based, machine learning model, and/or generative artificial intelligence model (e.g., model including at least one of one or more rule-based layers, one or more layers that depend on trained parameters, coefficients, and/or the like) configured to generate second item reconfiguration data. In this regard, in some embodiments, the related item benchmark machine learning component 306 may be configured to utilize one or more of any type of machine learning rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. In some embodiments, the related item benchmark machine learning component 306 is one component of the composite item design optimization machine learning model 300. In this regard, in some embodiments, the related item benchmark machine learning component 306 is configured to communicate with one or more other components of the composite item design optimization machine learning model 300 via a bus 312.

In some embodiments, generating second item reconfiguration data includes the related item benchmark machine learning component 306 identifying one or more features of the first item. In some embodiments, the one or more features of the first item are identified using the one or more images and one or more computer vision techniques. Additionally, or alternatively, one or more features of the first item are identified using first item reconfiguration data that is generated by the tear down machine learning component 302. In some embodiments, generating second item reconfiguration data includes the related item benchmark machine learning component 306 identifying one or more features of the related item. In some embodiments, the one or more features of the related item are identified using external related item data. For example, the one or more features of the related item may be identified using one or more related images associated with the external related item data and/or using one or more computer vision techniques. In some embodiments, generating second item reconfiguration data includes the related item benchmark machine learning component 306 determining one or more differences between the features of the first item and the features of the related item.

In some embodiments, generating second item reconfiguration data includes the related item benchmark machine learning component 306 determining one or more actions that may be performed to improve the first item. In this regard, in some embodiments, second item reconfiguration data includes one or more items of data representative and/or indicative of one or more actions that may be performed to improve the first item that are determined by applying one or more images associated with the first item and/or external related item data to a related item benchmark machine learning component 306 of the composite item design optimization machine learning model 300. Additionally, or alternatively, second item reconfiguration data includes one or more items of data representative and/or indicative of one or more actions that may be performed to improve the first item that are determined by applying an item specification associated with the first item and/or an item specification associated with the related item to the related item benchmark machine learning component 306 of the composite item design optimization machine learning model 300. Said differently, for example, the one or more actions represented by the second item reconfiguration data may be actions that may be performed to improve the first item based on one or more differences between the first item and the related item. In this regard, in some embodiments, second item reconfiguration data is representative and/or indicative of one or more actions that may be performed to improve the first item that include reducing the number of components of the first item. For example, if the related item benchmark machine learning component 306 determines that the related item has the same or similar functionality as the first item but uses fewer components, second item reconfiguration data may be representative and/or indicative of one or more actions that may be performed to improve the first item that include replacing components of the first item with the same type of components as used in the related item.

In some embodiments, second item reconfiguration data is representative and/or indicative of one or more actions that may be performed to improve the first item that include eliminating unnecessary manufacturing steps for creating and/or generating the first item. For example, if the related item benchmark machine learning component 306 determines that the related item has the same or similar functionality as the first item but is created and/or generated using fewer manufacturing steps, second item reconfiguration data may be representative and/or indicative of one or more actions that include using the manufacturing process associated with the related item for creating and/or generating the first item. In some embodiments, second item reconfiguration data is representative and/or indicative of one or more actions that may be performed to improve the first item that include substituting complex tooling associated with generating and/or creating the first item. For example, if the related item benchmark machine learning component 306 determines that the related item has the same or similar functionality as the first item but is created and/or generated using simpler tooling, second item reconfiguration data may be representative and/or indicative of one or more actions that include using tooling associated with the related item for creating and/or generating the first item. In some embodiments, second item reconfiguration data is representative and/or indicative of one or more actions that may be performed to improve the first item that include replacing a material in the first item with another material. In some embodiments, second item reconfiguration data is representative and/or indicative of one or more actions that may be performed to improve the first item that include changing a type of fastener used in the first item. In some embodiments, second item reconfiguration data is representative and/or indicative of one or more actions that may be performed to improve the first item that include changing a surface treatment associated with the first item. In some embodiments, second item reconfiguration data is representative and/or indicative of one or more actions that may be performed to improve the first item that include changing a structural design associated with the first item. In some embodiments, second item reconfiguration data is associated with item design optimization implementation data. In this regard, in some embodiments, the item design optimization device 140 is configured to generate item design optimization implementation data that includes second item reconfiguration data.

In some embodiments, the item design optimization device 140 is configured to receive impact value base data. In some embodiments, impact value base data includes one or more items of data representative and/or indicative of an impact value associated with a plurality of components that may be included in the first item and/or one or more other items. Additionally, or alternatively, impact value base data includes one or more items of data representative and/or indicative of an impact value associated with a plurality of manufacturing processes that may be used to create and/or generate the first item and/or one or more other items. In some embodiments, impact value base data is stored in an impact value database. In this regard, for example, the item design optimization device 140 is configured to receive impact value base data from the impact value database. In some embodiments, impact value base data is associated with item design configuration data. In this regard, for example, the item design optimization device 140 may be configured to receive item design configuration data that includes impact value base data.

In some embodiments, the item design optimization device 140 is configured to generate third item reconfiguration data by applying the impact value base data to an impact value determination machine learning component 308 of the composite item design optimization machine learning model 300. In some embodiments, third item reconfiguration data includes one or more items of data representative and/or indicative of an impact value associated with the components of the first item. Additionally, or alternatively, third item reconfiguration data includes one or more items of data representative and/or indicative of an impact value associated with a manufacturing process for generating and/or creating the first item. In this regard, in some embodiments, the impact value determination machine learning component 308 is configured to determine third item reconfiguration data by referencing impact value base data to determine an impact value associated with the components of the first item and/or an impact value associated with a manufacturing process used to create and/or generate the first item. In some embodiments, third item reconfiguration data is associated with item design optimization implementation data. In this regard, in some embodiments, the item design optimization device 140 is configured to generate item design optimization implementation data that includes third item reconfiguration data.

In some embodiments, the impact value determination machine learning component 308 may be a data entity that describes parameters, hyper-parameters, and/or defined operations of a rules-based, machine learning model, and/or generative artificial intelligence model (e.g., model including at least one of one or more rule-based layers, one or more layers that depend on trained parameters, coefficients, and/or the like) configured to generate third item reconfiguration data. In this regard, in some embodiments, the impact value determination machine learning component 308 may be configured to utilize one or more of any type of machine learning, rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. In some embodiments, the impact value determination machine learning component 308 is one component of the composite item design optimization machine learning model 300. In this regard, in some embodiments, the impact value determination machine learning component 308 is configured to communicate with one or more other components of the composite item design optimization machine learning model 300 via a bus 312.

In some embodiments, the item design optimization device 140 is configured to initiate performance of one or more optimized design implementation actions. In some embodiments, the item design optimization device 140 is configured to initiate performance of one or more optimized design implementation actions in response to generation of first item reconfiguration data, second item reconfiguration data, and/or third item reconfiguration data. In this regard, in some embodiments, the item design optimization device 140 is configured to initiate performance of one or more optimized design implementation actions using first item reconfiguration data, second item reconfiguration data, and/or third item reconfiguration data. In some embodiments, as described above, item design optimization implementation data includes first item reconfiguration data, second item reconfiguration data, and/or third item reconfiguration data. In this regard, in some embodiments, the item design optimization device 140 is configured to initiate performance of one or more optimized design implementation actions based on and/or using item design optimization implementation data.

In some embodiments, initiating performance of one or more optimized design implementation actions includes the item design optimization device 140 being configured to generate an item reconfiguration interface component 402. In some embodiments, the item reconfiguration interface component 402 includes a first item reconfiguration interface element 404 configured to display first item reconfiguration data. For example, the first item reconfiguration interface element 404 may be configured to display first item reconfiguration data representative and/or indicative of one or more actions that may be performed to improve the first item that include reducing the weight of a component of the first item (e.g., by replacing a component with a similar but lighter weight component). In some embodiments, the item reconfiguration interface component 402 includes a second item reconfiguration interface element 406 configured to display second item reconfiguration data. For example, the second item reconfiguration interface element 406 may be configured to display second item reconfiguration data representative and/or indicative of one or more actions that may be performed to improve the first item that include eliminating unnecessary manufacturing steps for creating and/or generating the first item. In some embodiments, the item reconfiguration interface component 402 includes a third item reconfiguration interface element 408 configured to display third item reconfiguration data. For example, the third item reconfiguration interface element 408 may be configured to display third item reconfiguration data representative and/or indicative of an impact value associated with the components of the first item.

In some embodiments, initiating performance of one or more optimized design implementation actions includes the item design optimization device 140 being configured to cause the item reconfiguration interface component 402 to be rendered to an item reconfiguration interface 400. In some embodiments, the item reconfiguration interface 400 may be provided on the item design optimization device 140. Additionally, or alternatively, the item reconfiguration interface 400 may be provided on the user device 160. Additionally, or alternatively, the item reconfiguration interface 400 may be provided on the augmented reality device 170.

In some embodiments, initiating performance of one or more optimized design implementation actions includes the item design optimization device 140 being configured to cause an item manufacturing procedure associated with the first item to be modified. In some embodiments, an item manufacturing procedure is a series of steps that are performed to generate and/or create the first item. In this regard, in some embodiments, the item design optimization device 140 is configured to cause an item manufacturing procedure associated with the first item to be modified based on first item reconfiguration data, second item reconfiguration data, and/or third item reconfiguration data. For example, the item design optimization device 140 may be configured to cause an item manufacturing procedure associated with the first to be modified such that a manufacturing step is eliminated from the manufacturing procedure when second item reconfiguration data indicates that the manufacturing step is unnecessary.

In some embodiments, initiating performance of one or more optimized design implementation actions includes the item design optimization device 140 being configured to cause an item component inventory record to be modified. In some embodiments, an item component inventory record is a record that indicates all of the components that are included in the first item. In this regard, for example, an item component inventory record may be modified to remove a component from the item component inventory record, such as when first reconfiguration data indicates that the first item can be improved by removing the component. In some embodiments, modifying an item component inventory record to remove a component may cause a transmission to be sent to a supplier to cancel an order for the removed component. As another example, an item component inventory record may be modified to replace a component from the item component inventory record with a similar component (e.g., a similar component with a lower impact value). In some embodiments, modifying an item component inventory record to replace a component with a similar component may cause a transmission to be sent to a supplier to cancel an order for the replaced component and/or place an order for the similar component.

In some embodiments, initiating performance of one or more optimized design implementation actions includes the item design optimization device 140 being configured to generate an item and related item comparison report. In some embodiments, the item design optimization device 140 being configured to generate an item and related item comparison report using first item reconfiguration data, second item reconfiguration data, third item reconfiguration data, one or more images associated with the first item, external related item data, and/or the like. In this regard, in some embodiments, the item and related item comparison report is a report that provides a comparison between the first item and the related item. In some embodiments, the item and related item comparison report may be in a tabular format. In some embodiments, the item and related item comparison report may include one or more images associated with the first item and/or one or more related item images. In some embodiments, initiating performance of one or more optimized design implementation actions may include causing the item and related item comparison report to be provided on the item reconfiguration interface component 402.

In some embodiments, the item design optimization device 140 is configured to cause a first image 504 of one or more images associated with the first item to be rendered to an item design visualization interface component 502. For example, the first image 504 may be a tear down image of the first item. In this regard, in some embodiments, the first image 504 includes one or more components of the first item, such as a first component 506.

In some embodiments, the item design optimization device 140 is configured to generate one or more augmented reality elements 508. In some embodiments, the item design optimization device 140 is configured to generate one or more augmented reality elements 508 by applying first item reconfiguration data, second item reconfiguration data, and/or third item reconfiguration data to an augmented reality machine learning component 310 of the composite item design optimization machine learning model 300. In this regard, for example, the augmented reality machine learning component 310 may be configured to generate the one or more augmented reality elements 508 such that the one or more augmented reality elements 508 include first item reconfiguration data, second item reconfiguration data, and/or third item reconfiguration data. For example, the augmented reality machine learning component 310 may be configured to generate the one or more augmented reality elements 508 such that the one or more augmented reality elements 508 indicate components of the first item that should be replaced based on first reconfiguration data.

In some embodiments, the augmented reality machine learning component 310 may be a data entity that describes parameters, hyper-parameters, and/or defined operations of a rules-based, machine learning model, and/or generative artificial intelligence model (e.g., model including at least one of one or more rule-based layers, one or more layers that depend on trained parameters, coefficients, and/or the like) configured to generate the one or more augmented reality elements 508. In this regard, in some embodiments, the augmented reality machine learning component 310 may be configured to utilize one or more of any type of machine learning, rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. In some embodiments, the augmented reality machine learning component 310 is one component of the composite item design optimization machine learning model 300. In this regard, in some embodiments, the augmented reality machine learning component 310 is configured to communicate with one or more other components of the composite item design optimization machine learning model 300 via a bus 312.

In some embodiments, the item design optimization device 140 is configured to cause at least one of the one or more augmented reality elements 508 to be overlaid the first image 504 on the item design visualization interface component 502. In some embodiments, the position at which the one or more augmented reality elements 508 are overlaid the first image 504 are adjustable based on user inputs and/or updates to first item reconfiguration data, second item reconfiguration data, and/or third item reconfiguration data. Additionally, or alternatively, the item design optimization device 140 is configured to cause at least one of the one or more augmented reality elements 508 to be overlaid one or more material recommendations associated with the first item. Additionally, or alternatively, the item design optimization device 140 is configured to cause at least one of the one or more augmented reality elements 508 to be overlaid one or more redesign recommendations associated with the first item. Additionally, or alternatively, the item design optimization device 140 is configured to cause at least one of the one or more augmented reality elements 508 to be overlaid one or more current materials associated with the first item. Additionally, or alternatively, the item design optimization device 140 is configured to cause at least one of the one or more augmented reality elements 508 to be overlaid one or more current manufacturing processes associated with the first item. Additionally, or alternatively, the item design optimization device 140 is configured to cause at least one of the one or more augmented reality elements 508 to be overlaid one or more assembly steps associated with the first item.

In some embodiments, the item design optimization device 140 is configured to cause the item design visualization interface component 502 to be rendered to an item design visualization interface 500. In some embodiments, the item design visualization interface 500 is provided on the item design optimization device 140. Additionally, or alternatively, the item design visualization interface 500 is provided on the user device 160. Additionally, or alternatively, the item design visualization interface 500 is provided on the augmented reality device 170.

### Example Methods

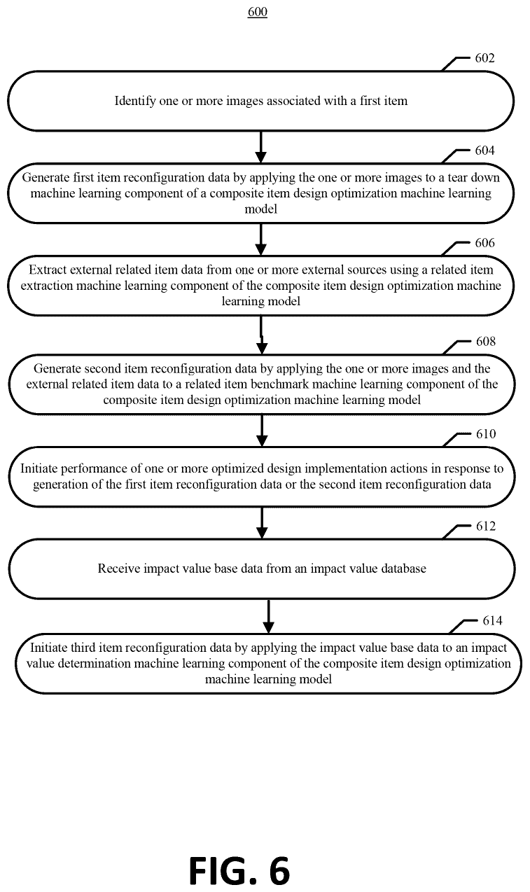

Referring now to FIG. 6, a flowchart providing an example method 600 is illustrated. In this regard, FIG. 6 illustrates operations that may be performed by the one or more of the one or more databases 150, the item design optimization device 140, the user device 160, the augmented reality device 170, and/or the like. In some embodiments, the method 600 includes operations for generating item reconfiguration data. In some embodiments, the example method 600 defines a process, which may be executable by any of the device(s) and/or system(s) embodied in hardware, software, firmware, and/or a combination thereof, as described herein. In some embodiments, computer program code including one or more computer-coded instructions are stored to at least one non-transitory computer-readable storage medium, such that execution of the computer program code initiates performance of the method 600.

As shown in block 602, the method 600 may include identifying one or more images associated with a first item. As described above, in some embodiments, the one or more images include images of a first item. For example, the one or more images may include images of a first item that includes a printed circuit board (PCB), a printed circuit board assembly (PCBA), a sensor, bar code scanner, and/or the like. In some embodiments, the one or more images include individual images of the first item, such as individual still images of the first item. For example, the one or more images may include one or more photos of the first item. In some embodiments, the one or more images include a series of images of the first item. For example, the one or more images may include a video of the first item. In some embodiments, the one or more images are captured using visible light, infrared, x-rays, and/or the like. In some embodiments, the one or more images include one or more tear down images of the first item. In this regard, for example, tear down images may include images of the first item after the first item has been taken apart and split into its components. As another example, tear down images may include images of the first item as the first item is being taken apart and split into the first item's components. Said differently, in some embodiments, the one or more images include tear down images that are configured to convey the first item's design, the first item's components, the first item's manufacturing process, and/or the like. In some embodiments, the one or more images are associated with item design configuration data. In this regard, for example, the item design optimization device may be configured to identify item design configuration data that includes one or more images.

In some embodiments, identifying one or more images associated with the first item includes the item design optimization device being configured to receive one or more images. For example, the item design optimization device may be configured to receive one or more images from the one or more databases, the augmented reality device, the user device, and/or one or more other sources (e.g., remote sources). Additionally, or alternatively, identifying one or more images includes the item design optimization device being configured to generate the one or more images associated with the first item. In this regard, for example, the item design optimization device may include one or more image capture components (e.g., a camera) configured to capture one or more images.

As shown in block 604, the method 600 may include generating first item reconfiguration data by applying the one or more images to a tear down machine learning component of a composite item design optimization machine learning model. As described above, in some embodiments, first item reconfiguration data includes one or more items of data representative and/or indicative of one or more features of the first item that are determined by applying one or more images to a tear down machine learning component of a composite item design optimization machine learning model. For example, first item reconfiguration data includes one or more items of data representative and/or indicative of one or more features of the first item that include a material from which the first item is constructed (e.g., the material of a layer of a PCB). As another example, first item reconfiguration data includes one or more items of data representative and/or indicative of one or more features of the first item that include a component of the first item (e.g., an electrical component, such as a capacitor, of a PCBA). As another example, first item reconfiguration data includes one or more items of data representative and/or indicative of one or more features of the first item that include a manufacturing process used to create and/or generate the first item (e.g., steps used to manufacture the first item). As another example, first item reconfiguration data includes one or more items of data representative and/or indicative of one or more features of the first item that include a machining process used to create and/or generate the first item (e.g., tools used to create a housing of a sensor).

Additionally, or alternatively, first item reconfiguration data includes one or more items of data representative and/or indicative of one or more actions that may be performed to improve the first item that are determined by applying one or more images to a tear down machine learning component of a composite item design optimization machine learning model. In this regard, in some embodiments, first item reconfiguration data may be representative and/or indicative of actions that may be performed to optimize the design of the first item. For example, first item reconfiguration data may be representative and/or indicative of one or more actions that may be performed to improve the first item that include reducing the weight of a component of the first item (e.g., by replacing a component with a similar but lighter weight component). As another example, first item reconfiguration data may be representative and/or indicative of one or more actions that may be performed to improve the first item that include replacing a component of the first item having a high impact value (e.g., a high cost) with a similar component having a lower impact value (e.g., a lower cost). As another example, first item reconfiguration data may be representative and/or indicative of one or more actions that may be performed to improve the first item that include performing fewer manufacturing steps to manufacture the first item (e.g., a more streamlined manufacturing process that eliminates redundant or inefficient steps). As another example, first item reconfiguration data may be representative and/or indicative of one or more actions that may be performed to improve the first item that include altering a manufacturing processes to rely less on specialized tools to generate and/or create the first item. As another example, first item reconfiguration data may be representative and/or indicative of one or more actions that may be performed to improve the first item that include replacing a material of an item with another material (e.g., replacing steel with plastic). In some embodiments, first item reconfiguration data is associated with item design optimization implementation data. In this regard, in some embodiments, the item design optimization device is configured to generate item design optimization implementation data that includes first item reconfiguration data.

In some embodiments, the tear down machine learning component may be a data entity that describes parameters, hyper-parameters, and/or defined operations of a rules-based, machine learning model, and/or generative artificial intelligence model (e.g., model including at least one of one or more rule-based layers, one or more layers that depend on trained parameters, coefficients, and/or the like) configured to generate first item reconfiguration data. In this regard, in some embodiments, the tear down machine learning component may be configured to utilize one or more of any type of machine learning, rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. For example, the tear down machine learning component may be configured to employ computer vision techniques to analyze one or more images to identify one or more features of the first item and/or one or more actions that may be performed to improve the first item. In some embodiments, the tear down machine learning component is one component of the composite item design optimization machine learning model. In this regard, in some embodiments, the tear down machine learning component is configured to communicate with one or more other components of the composite item design optimization machine learning model via a bus.

As shown in block 606, the method 600 may include extracting external related item data from one or more external sources using a related item extraction machine learning component of the composite item design optimization machine learning model. As described above, in some embodiments, the one or more external sources comprise an internet-based source. In some embodiments, external related item data includes one or more items of data representative and/or indicative of the related item. In this regard, for example, the related item may be an item that is related to the first item. In some embodiments, the related item is related to the first item because the related item and the first item have one or more features that are similar and/or in common with each other. For example, the related item may have one or more features that are similar and/or in common with the one or more features of the first item that were identified by the tear down machine learning component (e.g., when the tear down machine learning component generated first item reconfiguration data). Additionally, or alternatively, the related item and the first item may be related because the related item and the first item may have a common or similar manufacturing bill of materials (MBOM), a common or similar component specification, a common or similar manufacturing process and specification, a common or similar provider detail specification, and/or the like.

In some embodiments, the external related item data includes one or more related images. In some embodiments, the one or more related images include images of the related item. For example, the one or more related images may include images of a related item that includes a printed circuit board (PCB), a printed circuit board assembly (PCBA), a sensor, bar code scanner, and/or the like. In some embodiments, the one or more related images include individual images of the related item, such as individual still images of the related item. For example, the one or more related images may include one or more photos of the related item. In some embodiments, the one or more related images include a series of images of the related item. For example, the one or more related images may include a video of the related item. In some embodiments, the one or more related images are captured using visible light, infrared, x-rays, and/or the like. In some embodiments, the one or more related images include one or more tear down images of the related item. In this regard, for example, tear down images may include images of the related item after the related item has been taken apart and split into its components. As another example, tear down images may include images of the related item as the related item is being taken apart and split into the related item's components. Said differently, in some embodiments, the one or more related images include tear down images that are configured to convey the related item's design, the related item's components, the related item's manufacturing process, and/or the like. In some embodiments, the one or more related images are associated with item design configuration data. In this regard, for example, the item design optimization device may be configured to identify item design configuration data that includes one or more related images.

In some embodiments, the related item extraction machine learning component may be a data entity that describes parameters, hyper-parameters, and/or defined operations of a rules-based, machine learning model, and/or generative artificial intelligence model (e.g., model including at least one of one or more rule-based layers, one or more layers that depend on trained parameters, coefficients, and/or the like) configured to extract external related item data from one or more external sources. In this regard, in some embodiments, the related item extraction machine learning component may be configured to utilize one or more of any type of machine learning, rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. For example, if the related item extraction machine learning component may be configured to employ one or more fuzzy similarity techniques to identify and extract external related item data that is indicative of the related item based on the related item's commonality with the first item. In some embodiments, the related item extraction machine learning component is one component of the composite item design optimization machine learning model. In this regard, in some embodiments, the related item extraction machine learning component is configured to communicate with one or more other components of the composite item design optimization machine learning model via a bus.

As shown in block 608, the method 600 may include generating second item reconfiguration data by applying the one or more images and the external related item data to a related item benchmark machine learning component of the composite item design optimization machine learning model. As described above, in some embodiments, the item design optimization device is configured to generate second item reconfiguration data using a related item benchmark machine learning component of the composite item design optimization machine learning model. In some embodiments, the related item benchmark machine learning component may be a data entity that describes parameters, hyper-parameters, and/or defined operations of a rules-based, machine learning model, and/or generative artificial intelligence model (e.g., model including at least one of one or more rule-based layers, one or more layers that depend on trained parameters, coefficients, and/or the like) configured to generate second item reconfiguration data. In this regard, in some embodiments, the related item benchmark machine learning component may be configured to utilize one or more of any type of machine learning, rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. In some embodiments, the related item benchmark machine learning component is one component of the composite item design optimization machine learning model. In this regard, in some embodiments, the related item benchmark machine learning component is configured to communicate with one or more other components of the composite item design optimization machine learning model via a bus.

In some embodiments, generating second item reconfiguration data includes the related item benchmark machine learning component identifying one or more features of the first item. In some embodiments, the one or more features of the first item are identified using the one or more images and one or more computer vision techniques. Additionally, or alternatively, one or more features of the first item are identified using first item reconfiguration data that is generated by the tear down machine learning component. In some embodiments, generating second item reconfiguration data includes the related item benchmark machine learning component identifying one or more features of the related item. In some embodiments, the one or more features of the related item are identified using external related item data. For example, the one or more features of the related item may be identified using one or more related images associated with the external related item data and/or using one or more computer vision techniques. In some embodiments, generating second item reconfiguration data includes the related item benchmark machine learning component determining one or more differences between the features of the first item and the features of the related item.

In some embodiments, generating second item reconfiguration data includes the related item benchmark machine learning component determining one or more actions that may be performed to improve the first item. In this regard, in some embodiments, second item reconfiguration data includes one or more items of data representative and/or indicative of one or more actions that may be performed to improve the first item that are determined by applying one or more images associated with the first item and/or external related item data to a related item benchmark machine learning component of the composite item design optimization machine learning model. Additionally, or alternatively, second item reconfiguration data includes one or more items of data representative and/or indicative of one or more actions that may be performed to improve the first item that are determined by applying an item specification associated with the first item and/or an item specification associated with the related item to the related item benchmark machine learning component of the composite item design optimization machine learning model. Said differently, for example, the one or more actions represented by the second item reconfiguration data may be actions that may be performed to improve the first item based on one or more differences between the first item and the related item. In this regard, in some embodiments, second item reconfiguration data is representative and/or indicative of one or more actions that may be performed to improve the first item that include reducing the number of components of the first item. For example, if the related item benchmark machine learning component determines that the related item has the same or similar functionality as the first item but uses fewer components, second item reconfiguration data may be representative and/or indicative of one or more actions that may be performed to improve the first item that include replacing components of the first item with the same type of components as used in the related item.

In some embodiments, second item reconfiguration data is representative and/or indicative of one or more actions that may be performed to improve the first item that include eliminating unnecessary manufacturing steps for creating and/or generating the first item. For example, if the related item benchmark machine learning component determines that the related item has the same or similar functionality as the first item but is created and/or generated using fewer manufacturing steps, second item reconfiguration data may be representative and/or indicative of one or more actions that include using the manufacturing process associated with the related item for creating and/or generating the first item. In some embodiments, second item reconfiguration data is representative and/or indicative of one or more actions that may be performed to improve the first item that include substituting complex tooling associated with generating and/or creating the first item. For example, the related item benchmark machine learning component determines that the related item has the same or similar functionality as the first item but is created and/or generated using simpler tooling, second item reconfiguration data may be representative and/or indicative of one or more actions that include using tooling associated with the related item for creating and/or generating the first item. In some embodiments, second item reconfiguration data is representative and/or indicative of one or more actions that may be performed to improve the first item that include replacing a material in the first item with another material. In some embodiments, second item reconfiguration data is representative and/or indicative of one or more actions that may be performed to improve the first item that include changing a type of fastener used in the first item. In some embodiments, second item reconfiguration data is representative and/or indicative of one or more actions that may be performed to improve the first item that include changing a surface treatment associated with the first item. In some embodiments, second item reconfiguration data is representative and/or indicative of one or more actions that may be performed to improve the first item that include changing a structural design associated with the first item. In some embodiments, second item reconfiguration data is associated with item design optimization implementation data. In this regard, in some embodiments, the item design optimization device is configured to generate item design optimization implementation data that includes second item reconfiguration data.

As shown in block 610, the method 600 may include initiating performance of one or more optimized design implementation actions in response to generation of the first item reconfiguration data or the second item reconfiguration data. As described above, in some embodiments, the item design optimization device is configured to initiate performance of one or more optimized design implementation actions in response to generation of first item reconfiguration data, second item reconfiguration data, and/or third item reconfiguration data. In this regard, in some embodiments, the item design optimization device is configured to initiate performance of one or more optimized design implementation actions using first item reconfiguration data, second item reconfiguration data, and/or third item reconfiguration data. In some embodiments, as described above, item design optimization implementation data includes first item reconfiguration data, second item reconfiguration data, and/or third item reconfiguration data. In this regard, in some embodiments, the item design optimization device is configured to initiate performance of one or more optimized design.

As shown in block 612, the method 600 may include receiving impact value base data from an impact value database. As described above, in some embodiments, impact value base data includes one or more items of data representative and/or indicative of an impact value associated with a plurality of components that may be included in the first item and/or one or more other items. Additionally, or alternatively, impact value base data includes one or more items of data representative and/or indicative of an impact value associated with a plurality of manufacturing processes that may be used to create and/or generate the first item and/or one or more other items. In some embodiments, impact value base data is stored in an impact value database. In this regard, for example, the item design optimization device is configured to receive impact value base data from the impact value database. In some embodiments, impact value base data is associated with item design configuration data. In this regard, for example, the item design optimization device may be configured to receive item design configuration data that includes impact value base data.

As shown in block 614, the method 600 may include generating third item reconfiguration data by applying the impact value base data to an impact value determination machine learning component of the composite item design optimization machine learning model. As described above, in some embodiments, third item reconfiguration data includes one or more items of data representative and/or indicative of an impact value associated with the components of the first item. Additionally, or alternatively, third item reconfiguration data includes one or more items of data representative and/or indicative of an impact value associated with a manufacturing process for generating and/or creating the first item. In this regard, in some embodiments, the impact value determination machine learning component is configured to determine third item reconfiguration data by referencing impact value base data to determine an impact value associated with the components of the first item and/or an impact value associated with a manufacturing process used to create and/or generate the first item. In some embodiments, third item reconfiguration data is associated with item design optimization implementation data. In this regard, in some embodiments, the item design optimization device is configured to generate item design optimization implementation data that includes third item reconfiguration data.

In some embodiments, the impact value determination machine learning component may be a data entity that describes parameters, hyper-parameters, and/or defined operations of a rules-based, machine learning model, and/or generative artificial intelligence model (e.g., model including at least one of one or more rule-based layers, one or more layers that depend on trained parameters, coefficients, and/or the like) configured to generate third item reconfiguration data. In this regard, in some embodiments, the impact value determination machine learning component may be configured to utilize one or more of any type of machine learning, rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. In some embodiments, the impact value determination machine learning component is one component of the composite item design optimization machine learning model. In this regard, in some embodiments, the impact value determination machine learning component is configured to communicate with one or more other components of the composite item design optimization machine learning model via a bus.

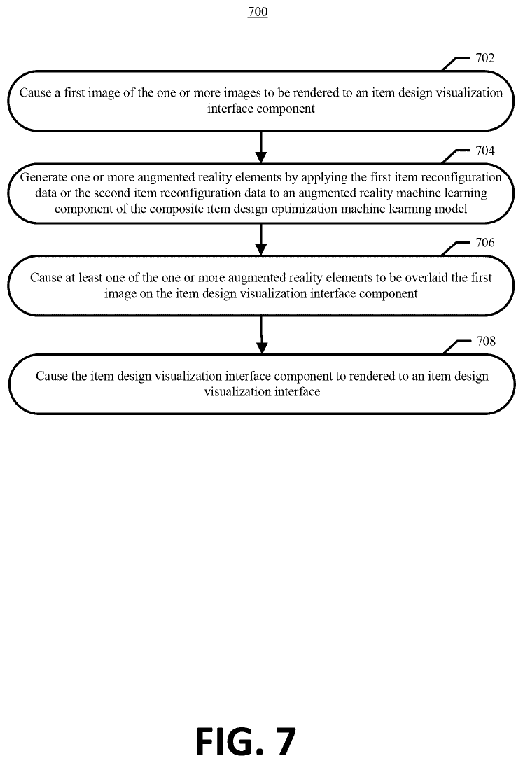

Referring now to FIG. 7, a flowchart providing an example method 700 is illustrated. In this regard, FIG. 7 illustrates operations that may be performed by the one or more of the one or more databases 150, the item design optimization device 140, the user device 160, the augmented reality device 170, and/or the like. In some embodiments, the method 700 includes operations for causing the item design visualization interface component to be rendered to an item design visualization interface. In some embodiments, the example method 700 defines a process, which may be executable by any of the device(s) and/or system(s) embodied in hardware, software, firmware, and/or a combination thereof, as described herein. In some embodiments, computer program code including one or more computer-coded instructions are stored to at least one non-transitory computer-readable storage medium, such that execution of the computer program code initiates performance of the method 700.

As shown in block 702, the method 700 may include a first image of the one or more images to be rendered to an item design visualization interface component. As described above, in some embodiments, the first image may be a tear down image of the first item. In this regard, in some embodiments, the first image includes one or more components of the first item, such as a first component.

As shown in block 704, the method 700 may include generating one or more augmented reality elements by applying the first item reconfiguration data or the second item reconfiguration data to an augmented reality machine learning component of the composite item design optimization machine learning model. As described above, in some embodiments, the item design optimization device is configured to generate one or more augmented reality elements by applying first item reconfiguration data, second item reconfiguration data, and/or third item reconfiguration data to an augmented reality machine learning component of the composite item design optimization machine learning model. In this regard, for example, the augmented reality machine learning component may be configured to generate the one or more augmented reality elements such that the one or more augmented reality elements include first item reconfiguration data, second item reconfiguration data, and/or third item reconfiguration data. For example, the augmented reality machine learning component may be configured to generate the one or more augmented reality elements such that the one or more augmented reality elements indicate components of the first item that should be replaced based on first reconfiguration data.

In some embodiments, the augmented reality machine learning component may be a data entity that describes parameters, hyper-parameters, and/or defined operations of a rules-based, machine learning model, and/or generative artificial intelligence model (e.g., model including at least one of one or more rule-based layers, one or more layers that depend on trained parameters, coefficients, and/or the like) configured to generate the one or more augmented reality elements. In this regard, in some embodiments, the augmented reality machine learning component may be configured to utilize one or more of any type of machine learning, rules-based, and/or artificial intelligence techniques including one or more of computer vision techniques, supervised learning (e.g., using user feedback), unsupervised learning, semi-supervised learning, reinforcement learning, computer vision techniques, sequence modeling techniques, language processing techniques, neural network techniques, and/or generative artificial intelligence techniques. In some embodiments, the augmented reality machine learning component is one component of the composite item design optimization machine learning model. In this regard, in some embodiments, the augmented reality machine learning component is configured to communicate with one or more other components of the composite item design optimization machine learning model via a bus.

As shown in block 706, the method 700 may include causing at least one of the one or more augmented reality elements to be overlaid the first image on the item design visualization interface component. As described above, in some embodiments, the position at which the one or more augmented reality elements are overlaid the first image are adjustable based on user inputs and/or updates to first item reconfiguration data, second item reconfiguration data, and/or third item reconfiguration data. Additionally, or alternatively, the item design optimization device is configured to cause at least one of the one or more augmented reality elements to be overlaid one or more material recommendations associated with the first item. Additionally, or alternatively, the item design optimization device is configured to cause at least one of the one or more augmented reality elements to be overlaid one or more redesign recommendations associated with the first item. Additionally, or alternatively, the item design optimization device is configured to cause at least one of the one or more augmented reality elements to be overlaid one or more current materials associated with the first item. Additionally, or alternatively, the item design optimization device is configured to cause at least one of the one or more augmented reality elements to be overlaid one or more current manufacturing processes associated with the first item. Additionally, or alternatively, the item design optimization device is configured to cause at least one of the one or more augmented reality elements to be overlaid one or more assembly steps associated with the first item.

As shown in block 708, the method 700 may include causing the item design visualization interface component to be rendered to an item design visualization interface. As described above, in some embodiments, the item design visualization interface is provided on the item design optimization device. Additionally, or alternatively, the item design visualization interface is provided on the user device. Additionally, or alternatively, the item design visualization interface is provided on the augmented reality device.

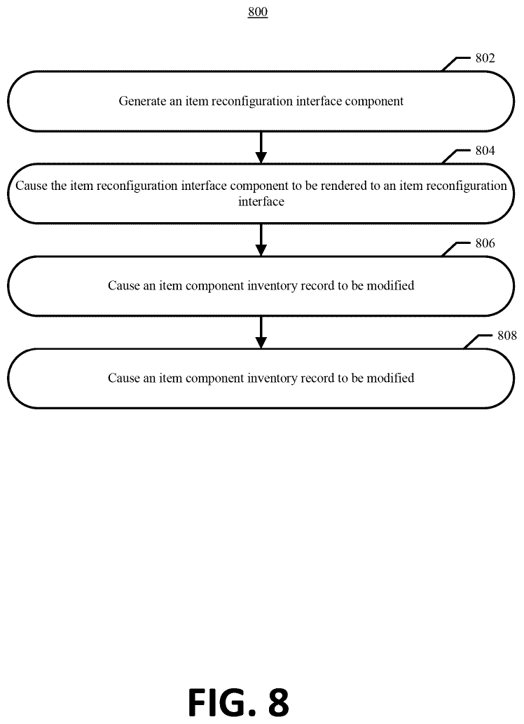

Referring now to FIG. 8, a flowchart providing an example method 800 is illustrated. In this regard, FIG. 8 illustrates operations that may be performed by the one or more of the one or more databases 150, the item design optimization device 140, the user device 160, the augmented reality device 170, and/or the like. In some embodiments, the method 800 includes operations for initiating performance of one or more optimized design implementation actions. In some embodiments, the example method 800 defines a process, which may be executable by any of the device(s) and/or system(s) embodied in hardware, software, firmware, and/or a combination thereof, as described herein. In some embodiments, computer program code including one or more computer-coded instructions are stored to at least one non-transitory computer-readable storage medium, such that execution of the computer program code initiates performance of the method 800.

As shown in block 802, the method 800 may include generating an item reconfiguration interface component. As described above, in some embodiments, the item reconfiguration interface component includes a first item reconfiguration interface element configured to display first item reconfiguration data. For example, the first item reconfiguration interface element may be configured to display first item reconfiguration data representative and/or indicative of one or more actions that may be performed to improve the first item that include reducing the weight of a component of the first item (e.g., by replacing a component with a similar but lighter weight component). In some embodiments, the item reconfiguration interface component includes a second item reconfiguration interface element configured to display second item reconfiguration data. For example, the second item reconfiguration interface element may be configured to display second item reconfiguration data representative and/or indicative of one or more actions that may be performed to improve the first item that include eliminating unnecessary manufacturing steps for creating and/or generating the first item. In some embodiments, the item reconfiguration interface component includes a third item reconfiguration interface element configured to display third item reconfiguration data. For example, the third item reconfiguration interface element may be configured to display third item reconfiguration data representative and/or indicative of an impact value associated with the components of the first item.

As shown in block 804, the method 800 may include causing the item reconfiguration interface component to be rendered to an item reconfiguration interface. As described above, in some embodiments, the item reconfiguration interface may be provided on the item design optimization device. Additionally, or alternatively, the item reconfiguration interface may be provided on the user device. Additionally, or alternatively, the item reconfiguration interface may be provided on the augmented reality device.

As shown in block 806, the method 800 may include causing an item component inventory record to be modified. As described above, in some embodiments, an item component inventory record is a record that indicates all of the components that are included in the first item. In this regard, for example, an item component inventory record may be modified to remove a component from the item component inventory record, such as when first reconfiguration data indicates that the first item can be improved by removing the component. In some embodiments, modifying an item component inventory record to remove a component may cause a transmission to be sent to a supplier to cancel an order for the removed component. As another example, an item component inventory record may be modified to replace a component from the item component inventory record with a similar component (e.g., a similar component with a lower impact value). In some embodiments, modifying an item component inventory record to replace a component with a similar component may cause a transmission to be sent to a supplier to cancel an order for the replaced component and/or place an order for the similar component.

As shown in block 808, the method 800 may include causing an item manufacturing procedure associated with the first item to be modified. As described above, in some embodiments, an item manufacturing procedure is a series of steps that are performed to generate and/or create the first item. In this regard, in some embodiments, the item design optimization device is configured to cause an item manufacturing procedure associated with the first item to be modified based on first item reconfiguration data, second item reconfiguration data, and/or third item reconfiguration data. For example, the item design optimization device may be configured to cause an item manufacturing procedure associated with the first to be modified such that a manufacturing step is eliminated from the manufacturing procedure when second item reconfiguration data indicates that the manufacturing step is unnecessary.

Operations and/or functions of the present disclosure have been described herein, such as in flowcharts. As will be appreciated, computer program instructions may be loaded onto a computer or other programmable apparatus (e.g., hardware) to produce a machine, such that the resulting computer or other programmable apparatus implements the operations and/or functions described in the flowchart blocks herein. These computer program instructions may also be stored in a computer-readable memory that may direct a computer, processor, or other programmable apparatus to operate and/or function in a particular manner, such that the instructions stored in the computer-readable memory produce an article of manufacture, the execution of which implements the operations and/or functions described in the flowchart blocks. The computer program instructions may also be loaded onto a computer, processor, or other programmable apparatus to cause a series of operations to be performed on the computer, processor, or other programmable apparatus to produce a process such that the instructions executed on the computer, processor, or other programmable apparatus provide operations for implementing the functions and/or operations specified in the flowchart blocks. The flowchart blocks support combinations of means for performing the specified operations and/or functions and combinations of operations and/or functions for performing the specified operations and/or functions. It will be understood that one or more blocks of the flowcharts, and combinations of blocks in the flowcharts, can be implemented by special purpose hardware-based computer systems which perform the specified operations and/or functions, or combinations of special purpose hardware with computer instructions.

While this specification contains many specific embodiments and implementation details, these should not be construed as limitations on the scope of any disclosures or of what may be claimed, but rather as descriptions of features specific to particular embodiments of particular disclosures. Certain features that are described herein in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

While operations and/or functions are illustrated in the drawings in a particular order, this should not be understood as requiring that such operations and/or functions be performed in the particular order shown or in sequential order, or that all illustrated operations be performed, to achieve desirable results. In certain circumstances, operations and/or functions in alternative ordering may be advantageous. In some cases, the actions recited in the claims may be performed in a different order and still achieve desirable results. Thus, while particular embodiments of the subject matter have been described, other embodiments are within the scope of the following claims.

Similarly, while operations are illustrated in the drawings in a particular order, this should not be understood as requiring that such operations be performed in the particular order shown or in sequential order, or that all illustrated operations be performed, to achieve desirable results. In certain circumstances, operations in alternative ordering may be advantageous. In some cases, the actions recited in the claims may be performed in a different order and still achieve desirable results.

1. A method comprising:
identifying one or more images associated with a first item;
generating first item reconfiguration data by applying the one or more images to a tear down machine learning component of a composite item design optimization machine learning model;
extracting external related item data from one or more external sources using a related item extraction machine learning component of the composite item design optimization machine learning model, wherein the external related item data is associated with a related item;
generating second item reconfiguration data by applying the one or more images and the external related item data to a related item benchmark machine learning component of the composite item design optimization machine learning model; and
initiating performance of one or more optimized design implementation actions in response to generation of the first item reconfiguration data or the second item reconfiguration data.

2. The method of claim 1, wherein the external related item data comprises one or more related images associated with the related item.

3. The method of claim 2, wherein the one or more external sources comprise an internet-based source.

4. The method of claim 1, further comprising:
receiving impact value base data from an impact value database; and
generating third item reconfiguration data by applying the impact value base data to an impact value determination machine learning component of the composite item design optimization machine learning model.

5. The method of claim 1, further comprising:
causing a first image of the one or more images to be rendered to an item design visualization interface component;
generating one or more augmented reality elements by applying the first item reconfiguration data or the second item reconfiguration data to an augmented reality machine learning component of the composite item design optimization machine learning model; and
causing at least one of the one or more augmented reality elements to be overlaid the first image on the item design visualization interface component.

6. The method of claim 5, further comprising:
causing the item design visualization interface component to be rendered to an item design visualization interface.

7. The method of claim 6, wherein the item design visualization interface is provided on an augmented reality device.

8. The method of claim 1, wherein the tear down machine learning component is configured to perform one or more computer vision techniques.

9. The method of claim 1, wherein initiating performance of the one or more optimized design implementation actions comprises:
causing an item manufacturing procedure associated with the first item to be modified.

10. The method of claim 1, wherein initiating performance of the one or more optimized design implementation actions comprises:
generating an item reconfiguration interface component, wherein the item reconfiguration interface component comprises one or more of the first item reconfiguration data, the second item reconfiguration data, or third item reconfiguration data; and
causing the item reconfiguration interface component to be rendered to an item reconfiguration interface.

11. The method of claim 1, wherein initiating performance of the one or more optimized design implementation actions comprises:
causing an item component inventory record to be modified.

12. An apparatus comprising memory and one or more processors communicatively coupled to the memory, the one or more processors configured to:
identify one or more images associated with a first item ;
generate first item reconfiguration data by applying the one or more images to a tear down machine learning component of a composite item design optimization machine learning model;
extract external related item data from one or more external sources using a related item extraction machine learning component of the composite item design optimization machine learning model, wherein the external related item data is associated with a related item;
generate second item reconfiguration data by applying the one or more images and the external related item data to a related item benchmark machine learning component of the composite item design optimization machine learning model; and
initiate performance of one or more optimized design implementation actions in response to generation of the first item reconfiguration data or the second item reconfiguration data.

13. The apparatus of claim 12, wherein the external related item data comprises one or more related images associated with the related item.

14. The apparatus of claim 12, wherein the one or more processors are further configured to:
receive impact value base data from an impact value database; and
generate third item reconfiguration data by applying the impact value base data to an impact value determination machine learning component of the composite item design optimization machine learning model.

15. The apparatus of claim 12, wherein the one or more processors are further configured to:
cause a first image of the one or more images to be rendered to an item design visualization interface component;
generate one or more augmented reality elements by applying the first item reconfiguration data or the second item reconfiguration data to an augmented reality machine learning component of the composite item design optimization machine learning model; and
cause at least one of the one or more augmented reality elements to be overlaid the first image on the item design visualization interface component.

16. The apparatus of claim 15, wherein the one or more processors are further configured to:
cause the item design visualization interface component to be rendered to an item design visualization interface.

17. The apparatus of claim 12, wherein to initiate performance of the one or more optimized design implementation actions comprises the one or more processors being further configured to:
cause an item manufacturing procedure associated with the first item to be modified.

18. The apparatus of claim 12, wherein to initiate performance of the one or more optimized design implementation actions comprises the one or more processors being further configured to:
generate an item reconfiguration interface component, wherein the item reconfiguration interface component comprises one or more of the first item reconfiguration data, the second item reconfiguration data, or third item reconfiguration data; and
cause the item reconfiguration interface component to be rendered to an item reconfiguration interface.

19. The apparatus of claim 12, wherein to initiate performance of the one or more optimized design implementation actions comprises the one or more processors being further configured to:
cause an item component inventory record to be modified.

20. A computer program product comprising at least one non-transitory computer-readable storage medium having computer program code stored thereon that, in execution with at least one processor, configures the computer program product for:
identifying one or more images associated with a first item ;
generating first item reconfiguration data by applying the one or more images to a tear down machine learning component of a composite item design optimization machine learning model;
extracting external related item data from one or more external sources using a related item extraction machine learning component of the composite item design optimization machine learning model, wherein the external related item data is associated with a related item;
generating second item reconfiguration data by applying the one or more images and the external related item data to a related item benchmark machine learning component of the composite item design optimization machine learning model; and
initiating performance of one or more optimized design implementation actions in response to generation of the first item reconfiguration data or the second item reconfiguration data.
